(19) United States
(12) Patent Application Publication
(10) Pub. No.: US 2005/0174157 A1
(43) Pub. Date: Aug. 11, 2005

(54) Variable attenuation network

(75) Inventors: Pietro Antonio Paolo Calo', Laterza (IT); Philippe Sirito-Olivier, Carro par Martigues (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignees: STMicroelectronics S.r.I., Agrate Brianza (IT); STMicroelectronics SA, Montrouge (FR)

(21) Appl. No.: 11/051,137

(22) Filed: Feb. 4, 2005

(30) Foreign Application Priority Data
Feb. 6, 2004 (IT) VA2004A000005

(51) Int. Cl. H03L 5/00

(52) U.S. Cl. 327/308

(57) ABSTRACT

A variable attenuation network of an input voltage on an input node produces an attenuated voltage on an output node of the network, and includes a voltage divider with multiple-taps that are selectable for producing the attenuated voltage from a voltage applied on the terminals of the voltage divider. The attenuation network produces an output voltage with an attenuation ratio that is determined with at least twice the resolution of the voltage divider, because it includes at least one resistor that may be shorted by a low impedance by-pass line controlled by a switch and alternatively connected between the selected intermediate tap or any one of the two terminals of the voltage divider and the output node of the variable attenuation network, the input node of the attenuation network or a common ground node, respectively. By using more than one shortable resistor, multiple levels of resolution may be obtained.

### FIELD OF THE INVENTION

The present invention relates to the field of electronic circuits and more particularly, to a high resolution variable attenuation network.

### BACKGROUND OF THE INVENTION

In signal processing it is often required to vary the gain with which signals are amplified. Commonly, the signals to be amplified are input to a high gain amplifier, the gain of which may generally be larger than desired, thus the output of the high gain amplifier is attenuated to obtain a signal of desired amplitude.

Variable attenuation networks may include resistive voltage dividers, as depicted in FIG. 1a, or of resistive ladders, as that of FIG. 1b, with multiple selectable taps for obtaining a certain attenuation. The attenuation ratio is set by closing only one of the N switches, controlled by a dedicated control circuit (not shown in the FIGURE) through the command DIGITAL CONTROL. With such conventional attenuation networks, it is not possible to continuously vary the attenuation ratio because only N pre-established values are provided, but it can be increased or decreased stepwise by a fixed quantity, thus the attenuation ratio is determined with a certain design resolution. To increase the resolution, it is necessary to re-design the attenuation network.

Because of the ever increasing precision levels required in electronic circuits, attenuation networks of high accuracy are needed. It would be desirable to find a simple expedient approach for enhancing the resolution of existing voltage dividers without the need of designing a new voltage divider when a higher resolution is required.

### SUMMARY OF THE INVENTION

The present invention is directed to an architecture of a variable attenuation network based on a voltage divider that allows the modification of the design attenuation ratios of the voltage divider. This is achieved by connecting at least a resistor that may be shorted by a switch, in series to the voltage divider.

More precisely, the invention provides a variable attenuation network of an input voltage on an input node and producing an attenuated voltage on an output node of the network, comprising a voltage divider with multiple-taps that are selectable for producing the attenuated voltage from a voltage applied on the terminals of the voltage divider. The attenuation network produces an output voltage with an attenuation ratio that is determined with at least twice the resolution of the voltage divider, because it comprises at least a resistor that may be shorted by a low impedance by-pass line controlled by a switch and alternatively connected between the selected intermediate tap or any one of the two terminals of the voltage divider and the output node of the variable attenuation network, the input node of the attenuation network or a common ground node, respectively. By using more than one shortable resistor, multiple levels of resolution may be obtained.

### BRIEF DESCRIPTION OF THE DRAWINGS

The various features and advantages of the invention will become even more evident through the following detailed description of embodiments and by referring to the attached drawings, wherein:

FIGS. 1A and 1B schematically illustrate known voltage dividers;

FIG. 2 is a schematic diagram showing a variable attenuation network of the present invention;

FIG. 3 is a schematic diagram of a preferred embodiment of a variable attenuation network of the invention.

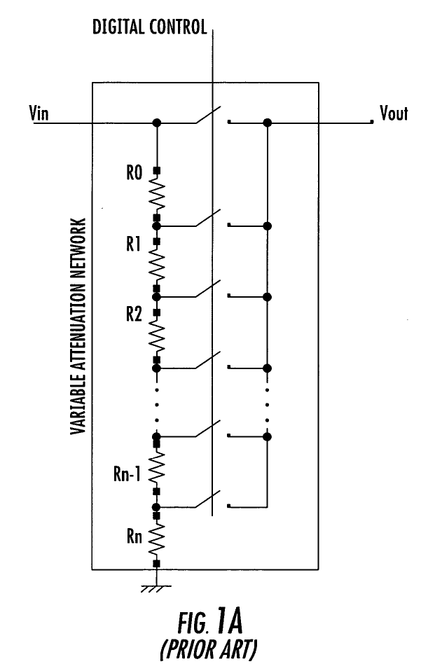

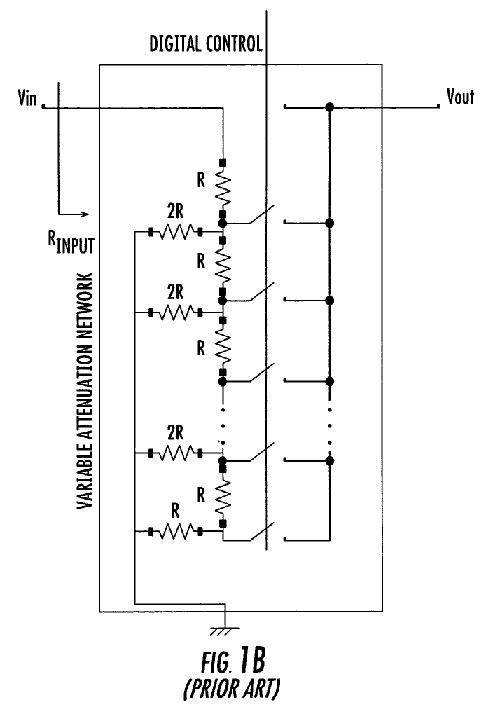

### DETAILED DESCRIPTION OF THE PREFERRED EMBODIMENTS

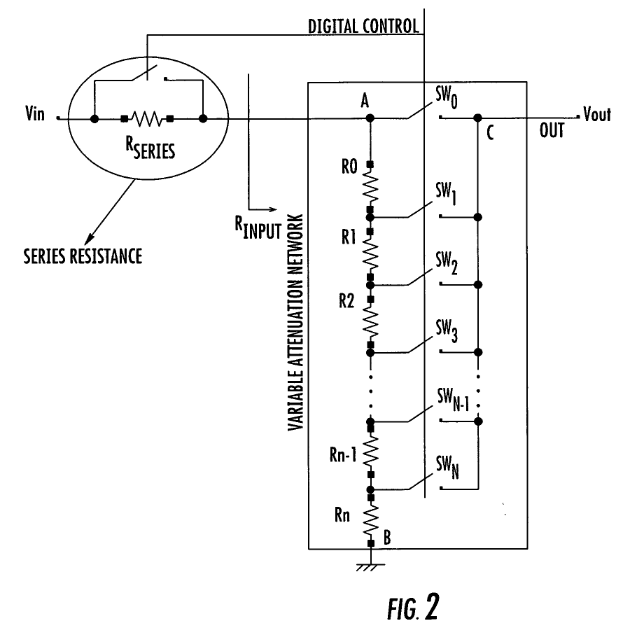

The variable attenuation network of th invention is obtained by connecting at least a resistor that may be shorted by a switch to a voltage divider and a first embodiment is shown in FIG. 2. By adding one or more resistors of appropriate value in series, upstream or downstream (between the resistor R_{N} and ground) of a voltage divider, or even between the selected tap (node C) and the output OUT of the attenuation network, the resolution of the voltage divider is enhanced without redesigning the voltage divider network in a simple and relatively inexpensive manner.

The embodiment of FIG. 2 will now be analyzed in detail and a skilled artisan will immediately recognize that the same considerations hold, with the necessary changes, even if the resistor R_{SERIES} is connected between the node B and ground or between the node C and the output node OUT of the attenuation network of this invention. Referring to FIG. 2, assume that only the switch SW_{X} is closed while all other switches are open. If the resistor R_{SERIES} is not shorted, the output voltage V_{OUT} is given by the following equation:

$${V}_{OUT} = \frac{{R}_{X} + ⋯ + {R}_{N}}{{R}_{SERIES} + {R}_{0} + ⋯ + {R}_{N}} \cdot {V}_{IN} \qquad ( 1 )$$

By appropriately choosing the resistor that may be shorted R_{SERIES}, a variable attenuation network with a resolution double that of the voltage divider per se is obtained. By indicating with OFFSET the desired variation in decibel of the attenuation ratio that is achieved by opening the switch that shorts the resistor R_{SERIES}, and with R_{INPUT} the input resistance of the voltage divider, the following equation holds:

$$OFFSET = 20 \cdot log ( \frac{1}{1 + \frac{{R}_{SERIES}}{{R}_{INPUT}}} ) \qquad ( 2 )$$

The great advantage offered by the attenuation network of this invention is even more evident if one considers that for doubling the resolution of a voltage divider for a certain input resistance R_{INPUT}, it is necessary to re-design the whole network, practically doubling the number of resistors composing the voltage divider.

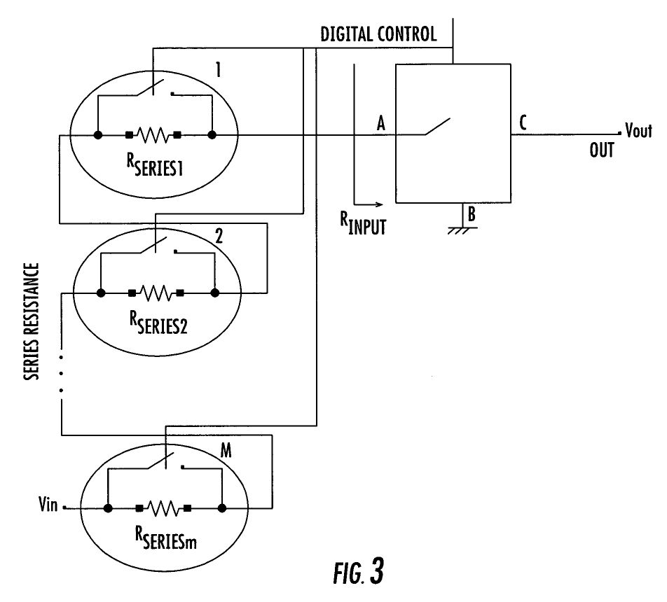

According to a preferred embodiment of this invention, more resistances R_{SERIESi} that may be equal to or even different from each other are connected in series upstream the voltage divider, as shown in FIG. 3, or alternatively between the resistor R_{N} and the ground node or even between the node C and the output OUT of the attenuation network, each resistor being shortable by a respective switch.

With M additional resistors R_{SERIESi}, according to the following equation:

$${OFFSET}_{i} = 20 \cdot log ( \frac{1}{1 + \frac{{R}_{SERIESi}}{{R}_{INPUT}}} ) i = 1 … M \qquad ( 3 )$$

it is possible to realize an attenuation network the attenuation factor of which may be varied by intermediate attenuation steps equal to a fraction of the minimum step change that is allowed by the voltage divider. The resolution may reach M+1 times the maximum resolution of the resistive voltage divider.

It should be noted that with the attenuation network of this invention even relatively small inaccuracies in realizing the resistors R_{SERIES} may negatively affect precision. The higher the resolution to be reached, the higher the accuracy with which these resistors must be realized. The attenuation is determined by a ratio of resistors, thus any rational attenuation value may be obtained by realizing the resistors of the attenuation network of this invention with appropriate resistance values by connecting in series or in parallel identical resistors of a single pre-defined value. For example, the attenuation network of FIG. 2 may be realized using identical resistors R₀, . . . , R_{N} and the resistor R_{SERIES} as the parallel between two resistors of value equal to R₀. This may be carried out with a very simple layout thus minimizing risks of eventual mismatches among resistors and with acceptable errors in producing the desired attenuation by the network.

As stated hereinbefore, it is possible to add the resistor(s) R_{SERIES} even between the node B and ground or between the node C and the output node OUT of the variable attenuation network. In the latter two cases the above discussed equations are no longer valid, but a skilled artisan will be recognize the appropriate equations (in lieu of equations (2) and (3)) for calculating the value of R_{SERIES} with respect to any desired resolution OFFSET.

1-4. (canceled)

5. A variable attenuation network comprising:
an input node;
an output node;
a voltage divider, having first and second terminals, and connected between the input node and the output node, and comprising a plurality of selectable output taps for attenuating a voltage applied to the first and second terminals of the voltage divider; and
at least one resistor circuit comprising a resistor shorted by a low impedance by-pass path controlled by a switch, and connected to the voltage divider.

6. A variable attenuation network according to claim 5, wherein the at least one resistor circuit is connected between one of a selected output tap, the first terminal and the second terminal, and one of the output node, the input node and a reference voltage node.

7. A variable attenuation network according to claim 5, wherein the at least one resistor circuit comprises a series of substantially identical resistor circuits.

8. A variable attenuation network according to claim 5, wherein a value of the resistor is a submultiple of an input resistance of the voltage divider.

9. A variable attenuation network according to claim 5, wherein each of the selectable output taps comprises a tap switch; and further comprising a control circuit for generating control signals for the tap switches and the switch of the at least one resistor circuit.

10. A variable attenuation network comprising:
a voltage divider comprising a plurality of selectable output taps for attenuating a voltage applied to the voltage divider; and
at least one resistor circuit connected to the voltage divider and comprising a selectively shortable resistor.

11. A variable attenuation network according to claim 10, wherein the at least one resistor circuit is connected between one of a selected output tap, and terminals of the voltage divider, and one of an output node, input node and a reference voltage node.

12. A variable attenuation network according to claim 10, wherein the at least one resistor circuit comprises a series of substantially identical resistor circuits.

13. A variable attenuation network according to claim 10, wherein a value of the resistor is a submultiple of an input resistance of the voltage divider.

14. A variable attenuation network according to claim 10, wherein each of the selectable output taps comprises a tap switch; wherein the selectively shortable resistor comprises a control switch; and further comprising a control circuit for generating control signals for the tap switches and the control switch of the at least one resistor circuit.

15. A method of making a variable attenuation network comprising:
attenuating a voltage applied to a voltage divider with a plurality of selectable output taps; and
selectively shorting a resistor of at least one resistor circuit connected to the voltage divider.

16. A method according to claim 15, wherein the at least one resistor circuit is connected between one of a selected output tap, and terminals of the voltage divider, and one of an output node, input node and a reference voltage node.

17. A method according to claim 15, wherein the at least one resistor circuit comprises a series of substantially identical resistor circuits.

18. A method according to claim 15, wherein a value of the resistor is a submultiple of an input resistance of the voltage divider.

19. A method according to claim 15, wherein each of the selectable output taps comprises a tap switch; wherein the selectively shortable resistor comprises a control switch; and further comprising generating control signals for the tap switches and the control switch of the at least one resistor circuit.
